(19) United States
(12) Patent Application Publication
(10) Pub. No.: US 2024/0124984 A1
(43) Pub. Date: Apr. 18, 2024

(54) SUBSTRATE PROCESSING APPARATUS AND SUBSTRATE GRIPPING DEVICE

(71) Applicant: Tokyo Electron Limited, Tokyo (JP)

(72) Inventors: Yusuke HASHIMOTO, Koshi City (JP); Daisuke GOTO, Koshi City (JP); Nobuhiro OGATA, Koshi City (JP); Jiro HIGASHIJIMA, Koshi City (JP); Tomoaki OBARU, Koshi City (JP); Kanta MORI, Koshi City (JP)

(21) Appl. No.: 18/483,608

(22) Filed: Oct. 10, 2023

(30) Foreign Application Priority Data
Oct. 12, 2022 (JP) 2022-163724

(51) Int. Cl. C23F 1/08

(52) U.S. Cl. CPC C23F 1/08; H01L 21/67023

(57) ABSTRACT

A substrate processing apparatus that supplies a processing liquid to a front surface of a substrate which is rotating, includes: a substrate holder configured to hold the substrate, wherein the substrate holder includes: a gripper configured to come into contact with a periphery of the substrate to grip the substrate; and a base to which the gripper is attached.

### CROSS-REFERENCE TO RELATED APPLICATION

This application is based upon and claims the benefit of priority from Japanese Patent Application No. 2022-163724, filed on Oct. 12, 2022, the entire contents of which are incorporated herein by reference.

### TECHNICAL FIELD

The present disclosure relates to a substrate processing apparatus and a substrate gripping device.

### BACKGROUND

Patent Document 1 discloses a substrate processing apparatus in which a substrate is held by a substrate holder and a processing liquid is supplied to the substrate which is rotating.

### PRIOR ART DOCUMENT

### Patent Document

Patent Document 1: Japanese Patent No. 5327144

### SUMMARY

According to one embodiment of the present disclosure, there is provided a substrate processing apparatus that supplies a processing liquid to a front surface of a substrate which is rotating, including: a substrate holder configured to hold the substrate, wherein the substrate holder includes: a gripper configured to come into contact with a periphery of the substrate to grip the substrate; and a base to which the gripper is attached.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a view illustrating a configuration of a substrate processing system according to an embodiment.

FIG. 2 is a view illustrating a configuration of a processing unit according to an embodiment.

FIG. 3 is a perspective view of a rotator according to an embodiment.

FIG. 4 is an exploded perspective view of the rotator according to the embodiment.

FIG. 5 is a plan view of the rotator according to the embodiment.

FIG. 6 is a front view of the rotator according to the embodiment.

FIG. 7 is a cross-sectional view taken along line VII-VII in FIG. 5.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, modes (hereinafter, referred to as “embodiments”) for implementing a substrate processing apparatus and a substrate gripping device according to the present disclosure will be described in detail with reference to the accompanying drawings. However, the substrate processing apparatus and the substrate gripping device according to the present disclosure are not limited by these embodiments.

In each of the drawings to be referred to below, for sake of convenience in description, an orthogonal coordinate system in which an X-axis direction, a Y-axis direction, and a Z-axis direction are orthogonal to each other may be defined, and a positive Z-axis direction is defined as a vertical upward direction.

### <Substrate Processing System>

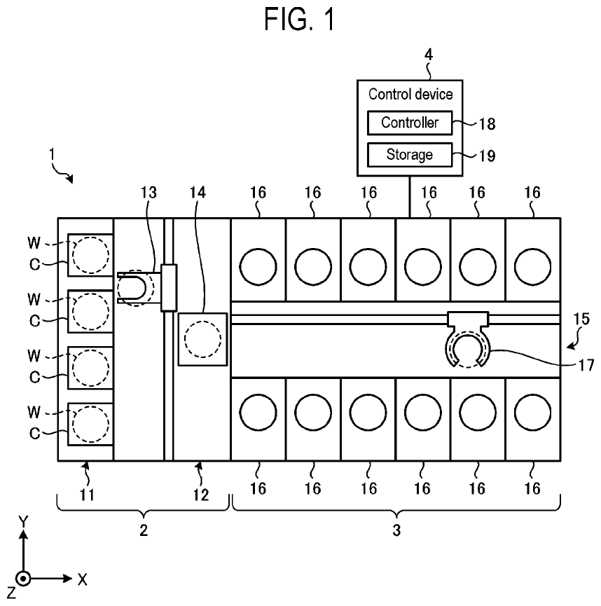

FIG. 1 is a view illustrating a configuration of a substrate processing system 1 according to an embodiment. As illustrated in FIG. 1, the substrate processing system 1 includes a carry-in/out station 2, and a processing station 3. The carry-in/out station 2 and the processing station 3 are provided adjacent to each other.

The carry-in/out station 2 includes a carrier stage 11 and a transporter 12. A plurality of carriers C configured to accommodate a plurality of substrates (hereinafter, referred to as “wafers W”) in a horizontal posture are placed on the carrier stage 11.

The transporter 12 is provided adjacent to the carrier stage 11 and includes a substrate transport device 13 and a deliverer 14 provided therein. The substrate transport device 13 includes a wafer holding mechanism configured to hold a wafer W. In addition, the substrate transport device 13 is movable in the horizontal direction and the vertical direction and rotatable about a vertical axis, and transports the wafer W between the carrier C and the deliverer 14 by using the wafer holding mechanism.

The processing station 3 is provided adjacent to the transporter 12. The processing station 3 includes a transporter 15 and a plurality of processing units 16 (an example of substrate processing apparatuses). The plurality of processing units 16 are arranged side by side on opposite sides of the transporter 15.

The transporter 15 includes a substrate transport device 17 provided therein. The substrate transport device 17 includes a substrate holding mechanism configured to hold the wafer W. In addition, the substrate transport device 17 is movable in the horizontal direction and the vertical direction and rotatable about a vertical axis, and transports the wafer W between the deliverer 14 and the processing unit 16 by using the substrate holding mechanism.

The processing unit 16 performs predetermined substrate processing on the wafer W transported thereto by the substrate transport device 17.

In addition, the substrate processing system 1 includes a control device 4. The control device 4 is, for example, a computer, and includes a controller 18 and a storage 19. The storage 19 stores programs for controlling various kinds of processing executed in the substrate processing system 1. The controller 18 controls the operation of the substrate processing system 1 by reading and executing the programs stored in the storage 19.

In addition, such programs may be stored in a non-transitory computer-readable storage medium, and may be installed in the storage 19 of the control device 4 from the storage medium. The computer-readable storage medium is, for example, a hard disk (HD), a flexible disk (FD), a compact disk (CD), a magneto-optical disk (MO), a memory card, or the like.

In the substrate processing system 1 configured as described above, first, the substrate transport device 13 of the carry-in/out station 2 takes out the wafer W from the carrier C placed in the carrier stage 11 and places the same on the deliverer 14. The wafer W placed on the deliverer 14 is taken out from the deliverer 14 by the substrate transport device 17 of the processing station 3 and is carried into the processing unit 16.

After the wafer W carried into the processing unit 16 is processed by the processing unit 16, the processed wafer W is carried out from the processing unit 16 and is placed on the deliverer 14 by the substrate transport device 17. Then, the processed wafer W placed on the deliverer 14 is returned to the carrier C in the carrier stage 11 by the substrate transport device 13.

### <Configuration of Processing Unit>

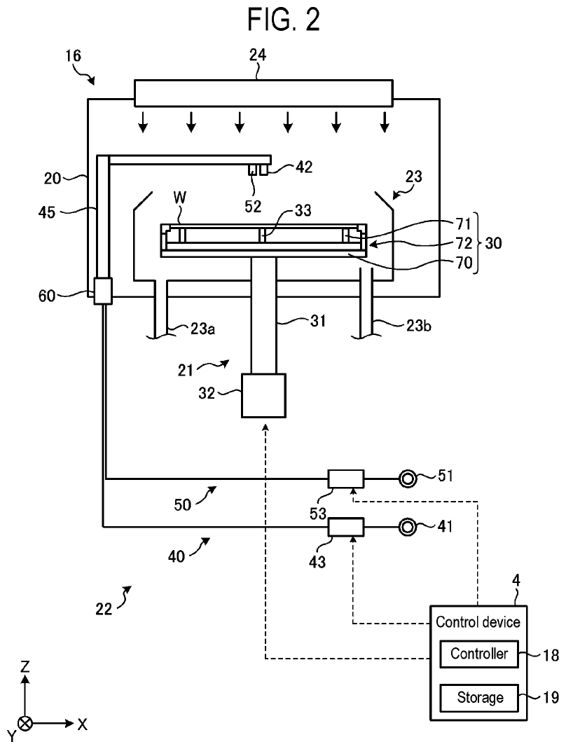

Next, a configuration of the processing unit 16 will be described with reference to FIG. 2. FIG. 2 is a view illustrating a configuration of the processing unit 16 according to an embodiment.

In an embodiment, the processing unit 16 illustrated in FIG. 2 supplies a processing liquid to the front surface (upper surface) of the wafer W and removes a film formed on the front surface. The processing unit 16 (an example of the substrate processing apparatus) supplies the processing liquid to the front surface of the wafer W (an example of the substrate) which is rotating. Processing in the processing unit 16 includes etching and resist stripping.

In another embodiment, the processing liquid is a sulfuric acid hydrogen peroxide mixture (SPM), which is a mixed liquid of sulfuric acid and hydrogen peroxide. The processing liquid is not limited to the SPM. The processing liquid may be SC1 (a mixed liquid of ammonia, hydrogen peroxide, and water), SC2 (a mixed liquid of hydrochloric acid, hydrogen peroxide, and water), hydrogen peroxide solution, or the like. The processing liquid is selected depending on the type of the film formed on the front surface of the wafer W. The processing unit 16 may supply a N₂ gas, which is a temperature-control gas to a rear surface (lower surface) of the wafer W.

The processing unit 16 includes a chamber 20, a substrate holding mechanism 21, a processing fluid supplier 22, and a recovery cup 23.

The chamber 20 accommodates a portion of the substrate holding mechanism 21, a portion of the processing fluid supplier 22, and the recovery cup 23. A ceiling portion of the chamber 20 is provided with a fan filter unit (FFU) 24. The FFU 24 forms a down-flow within the chamber 20.

The substrate holding mechanism 21 holds and rotates the wafer W. The substrate holding mechanism 21 includes a holder 30, a column 31, and a driver 32. The holder 30 (an example of a substrate holder) holds the wafer W (an example of the substrate). The holder 30 holds the wafer W in a horizontal posture. Details of the holder 30 will be described later.

The column 31 is a member extending in the vertical direction and has a base end portion that is rotatably supported by the driver 32, and a tip end portion that horizontally supports the holder 30. The driver 32 rotates the column 31 around a vertical axis. The driver 32 moves lift pins 33 in the vertical direction. The driver 32 includes, for example, a plurality of motors, gears configured to transmit a rotational force generated by the motors, link mechanisms, and the like.

As lift pins 33 are moved in the vertical direction by the driver 32, the wafer W is moved in the vertical direction. The lift pins 33 move vertically between a predetermined lowered position and a predetermined raised position.

The predetermined lowered position is a position where the wafer W is held by the holder 30 and is processed with the processing liquid. In the predetermined lowered position, the lift pins 33 are not in contact with the lower surface of the wafer W.

The predetermined raised position is a position where the carry-in/out of the wafer W is performed in the chamber 20. When the lift pins 33 are raised from the predetermined lowered position, the lift pins 33 come into contact with the lower surface of the wafer W and raise the wafer W. A plurality of lift pins 33 are provided at regular intervals along a circumferential direction of the wafer W. For example, three lift pins 33 are provided at intervals of 120 degrees along the circumferential direction of the wafer W. The number of lift pins 33 is not limited to three, and may be a number other than three.

The substrate holding mechanism 21 rotates the holder 30 supported by the column 31 by rotating the support column 31 with the driver 32. As a result, the wafer W held by the holder 30 rotates.

The processing fluid supplier 22 supplies the wafer W with various liquids used for substrate processing. The processing fluid supplier 22 includes a processing liquid supplier 40, a rinse liquid supplier 50, and an arm driver 60.

The processing liquid supplier 40 supplies the wafer W with the processing liquid. The processing liquid supplier 40 supplies the front surface of the wafer W with the processing liquid.

The processing liquid supplier 40 includes a processing liquid source 41, a processing liquid supply nozzle 42, and a processing liquid adjuster 43.

The processing liquid supply nozzle 42 is connected to the processing liquid source 41 via the processing liquid adjuster 43. The processing liquid supply nozzle 42 supplies the wafer W with the processing liquid. The processing liquid supply nozzle 42 is attached to the support arm 45.

The processing liquid adjuster 43 adjusts a flow rate of the processing liquid to be supplied from the processing liquid supply nozzle 42 to the front surface of the wafer W. The processing liquid adjuster 43 includes an opening/closing valve (not illustrated), a flow rate adjustment valve (not illustrated), a motor (not illustrated) configured to operate each valve, and the like.

The rinse liquid supplier 50 supplies the wafer W with a rinse liquid. The rinse liquid is deionized water (DIW). A temperature of the rinse liquid is, for example, normal temperature. The rinse liquid supplier 50 supplies the rinse liquid to the front surface of the wafer W.

The rinse liquid supplier 50 includes a rinse liquid source 51, a rinse liquid supply nozzle 52, and a rinse liquid adjuster 53.

The rinse liquid supply nozzle 52 supplies the front surface of the wafer W with the rinse liquid. The rinse liquid supply nozzle 52 is connected to the rinse liquid source 51 via the rinse liquid adjuster 53. The rinse liquid supply nozzle 52 is attached to the support arm 45.

The rinse liquid adjuster 53 adjusts a flow rate of the rinse liquid to be supplied to the front surface of the wafer W from the rinse liquid supply nozzle 52. The rinse liquid adjuster 53 includes an opening/closing valve (not illustrated), a flow rate adjustment valve (not illustrated), a motor (not illustrated) configured to operate each valve, and the like. The rinse liquid adjuster 53 is capable of adjusting the flow rate of the rinse liquid in the rinse liquid supply nozzle 52.

The arm driver 60 moves the support arm 45 in the vertical direction. The arm driver 60 rotates the support arm 45 around a vertical axis. In an embodiment, the arm driver 60 includes a plurality of motors, gears configured to transmit a rotational force generated by the motors, link mechanisms, and the like.

The arm driver 60 moves the processing liquid supply nozzle 42 and the rinse liquid supply nozzle 52 in a radial direction of the wafer W by rotating the support arm 45.

The arm driver 60 rotates the support arm 45 to move the processing liquid supply nozzle 42 and the rinse liquid supply nozzle 52 between a standby position and a central position. In the standby position, the processing liquid supply nozzle 42 and the rinse liquid supply nozzle 52 are not present above the wafer W, and no processing liquid or the like is supplied to the wafer W. In the central position, the processing liquid supply nozzle 42 and the rinse liquid supply nozzle 52 are present above the central portion of the wafer W, and the processing liquid or the like is supplied toward the central portion of the wafer W.

When moving the processing liquid supply nozzle 42 and the rinse liquid supply nozzle 52 from the standby position to the central position, the arm driver 60 moves the processing liquid supply nozzle 42 and the rinse liquid supply nozzle 52 from a peripheral portion of the wafer W toward the central portion of the wafer W. In addition, when moving the processing liquid supply nozzle 42 and the rinse liquid supply nozzle 52 from the central position to the standby position, the arm driver 60 rotates the support arm 45. As a result, the processing liquid supply nozzle 42 and the rinse liquid supply nozzle 52 move from the central portion of the wafer W toward the peripheral portion of the wafer W.

In addition, the rinse liquid supply nozzle 52 may be attached to a different support arm unlike the processing liquid supply nozzle 42. That is, a plurality of support arms may be provided. Respective support arms are moved and rotated by, for example, different arm drivers.

### <Configuration of Holder>

Next, the holder 30 will be described. The holder 30 includes a support table 70, support pins 71, and a rotator 72. The support table 70 is connected to the column 31. The support table 70 has a plate shape and is formed in, for example, a circular shape.

The support pins 71 are provided on the support table 70. The support pins 71 come into contact with the lower surface of the wafer W and support the wafer W in the state in which the wafer W is held by the rotator 72. A plurality of support pins 71 are provided along a circumferential direction of the support table 70. For example, six support pins 71 are provided along the circumferential direction of the support table 70. Three support pins 71 may be provided along the circumferential direction of the support table 70. The number of support pins 71 is not limited to the above-described numbers.

A plurality of rotators 72 are provided. The plurality of rotators 72 are provided at regular intervals along the circumferential direction of the support table 70. For example, three rotators 72 are provided at intervals of 120 degrees along the circumferential direction of the support table 70. The number of rotators 72 is not limited to three. The number of rotators 72 may be any number as long as they can rotatably hold the wafer W.

The rotators 72 are rotatable with respect to the support table 70. The rotators 72 are rotated and opened/closed by a motor (not illustration) and a transmission mechanism (not illustrated). When the rotators 72 are in the closed state, the wafer W is held by the rotators 72. When the rotators 72 are in the opened state, the wafer W is not held by the rotators 72.

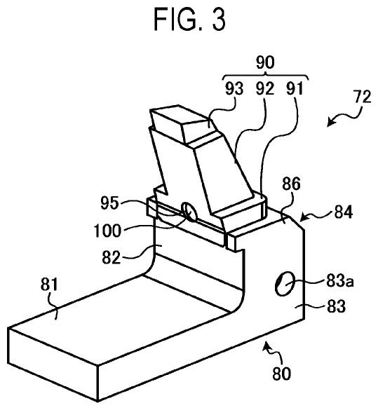

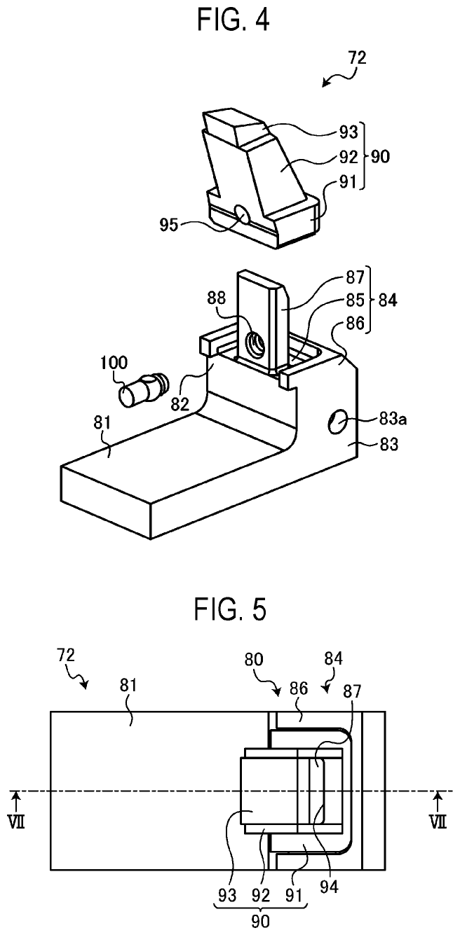

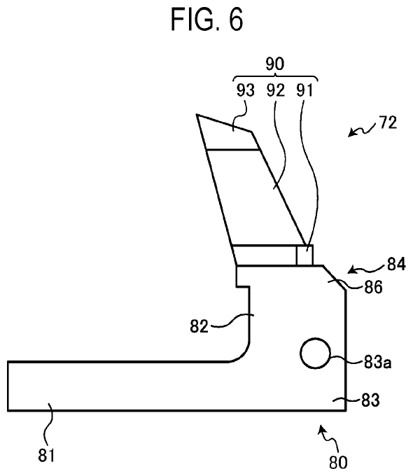

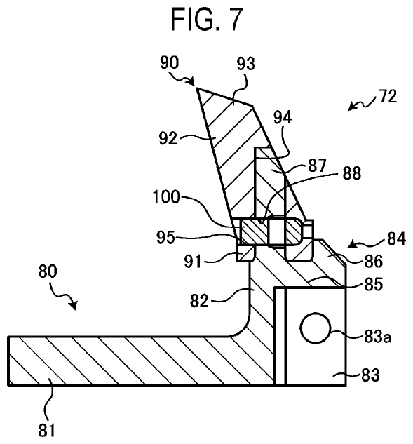

The rotators 72 will be described with reference to FIGS. 3 to 7. FIG. 3 is a perspective view of the rotator 72 according to an embodiment. FIG. 4 is an exploded perspective view of the rotator 72 according to the embodiment. FIG. 5 is a plan view of the rotator 72 according to the embodiment. FIG. 6 is a front view of the rotator 72 according to the embodiment. FIG. 7 is a cross-sectional view taken along line VII-VII in FIG. 5. The rotator 72 includes a base 80, a gripper 90, and a fixer 100.

The base 80 is rotatably attached to the support table 70. The base 80 is made of any one of silicon carbide (SiC), carbon-containing perfluoroalkoxy alkane (C-PFA), and carbon-containing polychlorotrifluoroethylene (C-PCTFE). The base 80 may be made of polyetheretherketone (PEEK). The base 80 may be made of stainless steel (SUS) coated with PFA. That is, the material of the base 80 is any one of PFA-coated SUS, SiC, C-PFA, C-PCTFE, and PEEK. For example, the base 80 is made of SiC. In addition, the above-mentioned “C (carbon)” includes carbon nanotube (CNT). The same applies to the following.

The gripper 90 is attached to the base 80. The base 80 includes a first plate portion 81, a second plate portion 82, a rotary shaft support 83, and a support 84. The base 80 is formed in a substantially L-like shape in a front view.

For example, the first plate portion 81 is provided to extend along the radial direction of the support table 70. In addition, the first plate portion 81 may be provided to extend along a direction inclined in the vertical direction with respect to the radial direction of the support table 70. The second plate portion 82 is provided to extend upward from an end portion of the first plate portion 81 on the outer side in the radial direction of the support table 70. In the following description, a central axis side of the support table 70 will be referred to as an “inner side”, and a peripheral side of the support table 70 will be referred to as an “outer side”.

The rotary shaft support 83 is provided to protrude toward the outer side from the second plate portion 82. For example, two rotary shaft supports 83 are provided. The number of rotary shaft supports 83 may be one. A support hole 83a is formed in the rotary shaft support 83. A rotation shaft (not illustrated) is inserted into the support hole 83a. The rotator 72 rotates around an axis of the rotary shaft. The rotator 72 rotates around the axis of the rotary shaft when power is transmitted from the transmission mechanism. As a result, the rotator 72 is opened and closed so that the wafer W is switched between a holding state and a non-holding state.

The support 84 is provided to be connected to an upper end of the second plate portion 82. The support 84 supports the gripper 90. The support 84 includes a stage 85, a frame 86, and an insert 87. The stage 85 is connected to the upper end of the second plate portion 82. The stage 85 is formed in, for example, a rectangular shape in a plan view.

The frame 86 is provided to extend upward from the periphery of the stage 85. The frame 86 is provided to open in the inner side. The frame 86 is provided in a substantially U-like shape. The frame 86 may be provided along the entire periphery of the stage 85. That is, the frame 86 may be provided as a rectangular frame.

The insert 87 is provided to extend upward from the stage 85. The insert 87 is provided inward of the frame 86. A base end portion 91 of the gripper 90 to be described later is partially inserted between the insert 87 and the frame 86. The insert 87 is provided to protrude upward from the frame 86. The insert 87 is inserted into an insertion hole 94 of the gripper 90.

A first through-hole 88 is formed in the insert 87. The first through-hole 88 is formed to penetrate the insert 87 from the inner side to the outer side. The first through-hole 88 is formed along, for example, the radial direction of the support table 70. The first through-hole 88 is formed to have an outer diameter smaller than an inner diameter thereof.

The gripper 90 (an example of a substrate gripping device) rotates together with the wafer W in the state of holding the wafer W (an example of the substrate), to the front surface of which the wafer W is supplied. The gripper 90 is attached to the base 80. The gripper 90 comes into contact with the periphery of the wafer W to grip the wafer W. The gripper 90 is made of a material suitable for a film formed on the front surface of the wafer W and the processing liquid. The gripper 90 is made of a material having chemical resistance to the processing liquid.

The gripper 90 may be detachably provided to the base 80. The gripper 90 may be replaced depending on the film formed on the front surface of the wafer W and the processing liquid. For example, when a metal film is formed on the front surface of the wafer W (an example of the substrate), the gripper 90 is made of a high-resistance material.

The high-resistance material is a material having a volume resistance value of 1.0×10⁵ Ωcm or more. The high-resistance material is, for example, any one of PFA-coated SUS, PFA-coated SiC, glass fiber-containing polytetrafluoroethylene-containing (GF-PTFE), PCTFE, and PEEK.

The metal film is any one of, for example, titanium nitride (TiN), cobalt (Co), nickel (Ni), tungsten (W), molybdenum (Mo), ruthenium (Ru), aluminum oxide (Al₂O₃), silicon germanium (SiGe), zirconia (ZrO₂), aluminum (Al), and copper (Cu).

In addition, for example, when a metal film is not formed on the front surface of the wafer W (an example of the substrate), the gripper 90 is made of a low-resistance material.

The low-resistance material is a material having a volume resistance value of less than 1.0×10⁵ Ωcm. The low-resistance material is, for example, any one of C-PFA, C-PCTFE, and C-PEEK. In addition, when no metal film is formed on the front surface of the wafer W, the gripper 90 may be made of a high-resistance material.

In addition, for example, when a temperature of the processing liquid is 50 degrees C. or higher, the gripper 90 is made of a low-thermal conductive material. The low-thermal conductive material is a material having a heat transfer coefficient of 1.0 W/mk or less. The low-thermal conductive material includes, for example, a resin member.

The gripper 90 includes the base end portion 91, an arm portion 92, and a claw portion 93. The base end portion 91 is partially inserted into the frame 86 of the base 80. The surrounding of the base end portion 91 is supported by the frame 86 of the base 80. The base end portion 91 is supported from below by the stage 85 of the base 80. The base end portion 91 is detachably attached to the base 80.

The arm portion 92 is provided to extend obliquely upward from the base end portion 91. The arm portion 92 is inclined such that an upper end side thereof is located inward of the base end portion 91. In addition, the arm portion 92 may be provided to extend upward from the base end portion 91.

The claw portion 93 is provided to extend upward from an upper end of the arm portion 92. The claw portion 93 is connected to the base end portion 91 and comes into contact the periphery of the wafer W (an example of the substrate) to grip the wafer W. The claw portion 93 is connected to the base end portion 91 via the arm portion 92. The claw portion 93 comes into contact with the periphery of the wafer W when the rotator 72 is in the closed state. The claw portion 93 is not in contact with the periphery of the wafer W when the rotator 72 is in the opened state.

An insertion hole 94 and a second through-hole 95 are formed in the gripper 90. The insertion hole 94 is formed to extend upward from a lower surface of the base end portion 91. The insert 87 of the base 80 is inserted into the insertion hole 94. The insertion hole 94 may be closed at its upper end.

The second through-hole 95 is formed to penetrate the gripper 90 from the inner side to the outer side. The second through-hole 95 is formed along, for example, the radial direction of the support table 70. The second through-hole 95 is formed to intersect with the insertion hole 94. The second through-hole 95 is formed to be in communication with the first through-hole 88 when the gripper 90 is attached to the base 80. For example, when the gripper 90 is attached to the base 80, the second through-hole 95 is formed coaxially with the first through-hole 88.

The fixer 100 fixes the gripper 90 to the base 80. The fixer 100 is, for example, a pin. The fixer 100 is inserted into the second through-hole 95 in the gripper 90 and the first through-hole 88 in the base 80. The fixer 100 is made of, for example, resin. The material of the fixer 100 is, for example, PTFE. The material of the fixer 100 may be the same material as the gripper 90 or the base 80.

When the gripper 90 is attached to the base 80, in the rotator 72, the insert 87 of the base 80 is inserted into the insertion hole 94 in the gripper 90. In addition, the base end portion 91 of the gripper 90 is inserted into the frame 86 of the base 80. A lower surface of the base end portion 91 comes into contact with the upper surface of the stage 85, and the gripper 90 is supported by the stage 85 from below. When the lower surface of the base end portion 91 is in contact with the upper surface of the stage 85, the second through-hole 95 in the gripper 90 and the first through-hole 88 in the base 80 coaxially communicate with each other.

Then, the fixer 100 is inserted into the second through-hole 95.

By inserting the fixer 100 into the first through-hole 88 in the gripper 90 and the second through-hole 95 in the base 80, the gripper 90 is prevented from coming off upward from the base 80.

When the gripper 90 is removed from the base 80, a removal pin or the like is inserted from the outer side into the second through-hole 95 in the gripper 90, and the fixer 100 is pushed toward the inner side (toward the first plate portion 81 of the base 80).

As a result, the fixer 100 is removed from the first through-hole 88 in the base 80 and the second through-hole 95 in the gripper 90.

As the fixer 100 comes off from the first through-hole 88 and the second through-hole 95, the gripper 90 may be removed from the base 80.

In a substrate processing apparatus according to Comparative Example that does not have the above-described holder 30, the rotator is constituted with a single component.

In the substrate processing apparatus according to Comparative Example, for example, when a portion that comes into contact with the wafer is deteriorated, the entire rotator is replaced.

In the substrate processing apparatus according to Comparative Example, for example, when a material having high chemical resistance to a processing liquid is selected as the material of the rotator, the strength and durability of the rotator may be reduced. Further, in the substrate processing apparatus according to Comparative Example, for example, when a material having high strength is selected as the material of the rotator, the chemical resistance of the rotator to the processing liquid may be reduced, which may degrade the rotator and reduce the durability of the rotator. That is, in the substrate processing apparatus according to Comparative Example, the durability of the rotator may be reduced, which may shorten the life of the rotator.

The processing unit 16 (an example of the substrate processing apparatus) according to an embodiment supplies the processing liquid to the front surface of the wafer W (an example of the substrate) which is rotating. The processing unit 16 includes the holder 30 (an example of the substrate holder). The holder 30 includes the gripper 90 and the base 80. The gripper 90 comes into contact with the periphery of the wafer W to grip the wafer W. The gripper 90 is attached to the base 80.

As a result, in the processing unit 16, when the gripper 90 is deteriorated, the gripper 90 may be removed from the base 80 to be replaced with a new one. Therefore, the processing unit 16 may provide an improved maintenance of the holder 30. In addition, in the processing unit 16, the gripper 90 may be easily replaced with one made of a material suitable for processing depending on the type of the processing liquid.

In addition, in the processing unit 16, for example, a material having high-chemical resistance to the processing liquid may be used as the material of the gripper 90 and a material with high strength may be used as the material of the base 80. As a result, in the processing unit 16, the durability of the holder 30 may be improved, which makes it possible to prolong the life of the holder 30.

The material of the base 80 is any one of PFA-coated SUS, SiC, C-PFA, C-PCTFE, and PEEK.

As a result, in the processing unit 16, the strength of the base 80 may be improved, which makes it possible to enhance the durability of the holder 30.

When a metal film is formed on the front surface of the wafer W, the gripper 90 is made of a high-resistance material. The high resistance material has a volume resistance value of 1.0×10⁵ Ωcm or more.

As a result, in the processing unit 16, when the processing liquid is supplied to the front surface of the wafer W, the metal film may be suppressed from being conductive with the gripper 90 due to the processing liquid, which makes it possible to suppress promotion of partial etching (so-called Galvanic corrosion) of the metal film on the wafer W. Therefore, with the processing unit 16, the uniformity of processing on the wafer W may be improved. For example, with the processing unit 16, the uniformity of etching on the wafer W may be improved.

The high-resistance material is any one of PFA-coated SUS, PFA-coated SiC, GF-PTFE, PCTFE, and PEEK.

As a result, with the processing unit 16, the uniformity of processing on the wafer W may be improved.

The metal film is any one of TiN, Co, Ni, W, Mo, Ru, Al₂O₃, SiGe, ZrO₂, Al, and Cu.

As a result, in the case where the wafer W on which various types of metal films are formed is processed with the processing liquid in the processing unit 16, the uniformity of processing on the wafer W may be improved.

When no metal film is formed on the front surface of the wafer W, the gripper 90 is made of a low-resistance material. The low-resistance material has a volume resistance volume of less than 1.0×10⁵ Ωcm.

As a result, in a case where the Galvanic corrosion does not occur on the wafer W in the processing unit 16, the selection range of the material of the gripper 90 may be widened. In addition, in the processing unit 16, charges accumulated on the wafer W may be reduced.

The low-resistance material is any one of C-PFA, C-PCTFE, and C-PEEK.

As a result, in the processing unit 16, the wafer W may be held by the gripper 90 made of a highly conductive material, which makes it possible to decrease the charges accumulated on the wafer W.

When the temperature of the processing liquid is 50 degrees C. or higher, the gripper 90 is made of a low-thermal conductive material. The low-thermal conductive material has a thermal conductivity of 1.0 W/mk or less.

As a result, in the processing unit 16, heat dissipation by the gripper 90 may be suppressed. For example, in a case where a resist on the wafer W is stripped by an SPM processing liquid with the processing unit 16, heat dissipation by the gripper 90 may be suppressed, which suppresses generation of resist residues.

The holder 30 includes the fixer 100 that fixes the gripper 90 to the base 80.

Thus, when the wafer W is rotated, in the processing unit 16, the holding of the wafer W by the gripper 90 may be prevented from being released.

The gripper 90 includes the base end portion 91 and the claw portion 93. The base end portion 91 is detachably attached to the base 80. The claw portion 93 is connected to the base end portion 91 and comes into contact with the periphery of the wafer W (an example of the substrate) to grip the wafer W.

As a result, for example, in a case where the claw portion 93 that comes into contact with the wafer W is deteriorated, the gripper 90 is removed from the base 80 to replace with a new one. Therefore, the maintenance of the gripper 90 may be improved. In addition, in the processing unit 16, the gripper 90 may be easily replaced with one made of a material suitable for processing depending on the type of the processing liquid.

The configuration of the fixer 100 that fixes the gripper 90 to the base 80 is not limited to the embodiment described above. The fixer 100 may be any type of fixer as long as it can detachably fix the gripper 90 to the base 80. For example, the fixer 100 may be a screw. Further, the fixer 100 may be formed integrally with the gripper 90 and the base 80. For example, the fixer 100 may be an engagement portion in which an engagement claw provided on one of the base 80 and the gripper 90 and an engagement claw provided on the other of the base 80 and the gripper 90 are engaged with each other.

According to the present disclosure, it is possible to improve maintainability of a substrate holder.

It should be noted that the embodiments disclosed herein are exemplary in all respects and are not restrictive. Indeed, the above-described embodiments may be implemented in various forms. The above-described embodiments may be omitted, replaced or modified in various forms without departing from the scope and spirit of the appended claims.

What is claimed is:

1. A substrate processing apparatus that supplies a processing liquid to a front surface of a substrate which is rotating, comprising:
a substrate holder configured to hold the substrate,
wherein the substrate holder comprises:
a gripper configured to come into contact with a periphery of the substrate to grip the substrate; and
a base to which the gripper is attached.

2. The substrate processing apparatus of claim 1, wherein a material of the base is any one of PFA-coated SUS, SiC, C-PFA, CPCTFE, and PEEK.

3. The substrate processing apparatus of claim 1, wherein, when a metal film is formed on the front surface of the substrate, the gripper is made of a high-resistance material, and
wherein the high-resistance material has a volume resistance value of 1.0×10⁵ Ωcm or more.

4. The substrate processing apparatus of claim 3, wherein the high-resistance material is any one of PFA-coated SUS, PFA-coated SiC, GF-PTFE, PCTFE, and PEEK.

5. The substrate processing apparatus of claim 4, wherein the metal film is made of any one of TiN, Co, Ni, W, Mo, Ru, Al₂O₃, SiGe, ZrO₂, Al, and Cu.

6. The substrate processing apparatus of claim 1, wherein, when no metal film is formed on the front surface of the substrate, the gripper is made of a low-resistance material, and
wherein the low-resistance material has a volume resistance value of less than 1.0×10⁵ Ωcm.

7. The substrate processing apparatus of claim 6, wherein the low-resistance material is any one of C-PFA, C-PCTFE, and C-PEEK.

8. The substrate processing apparatus of claim 1, wherein, when a temperature of the processing liquid is 50 degrees C. or higher, the gripper is made of a low-thermal conductive material, and
wherein the low-thermal conductive material has a thermal conductivity of 1.0 W/mk or less.

9. The substrate processing apparatus of claim 1, wherein the substrate holder includes a fixer configured to fix the gripper to the base.

10. The substrate processing apparatus of claim 3, wherein the metal film is made of any one of TiN, Co, Ni, W, Mo, Ru, Al₂O₃, SiGe, ZrO₂, Al, and Cu.

11. A substrate gripping device that rotates together with a substrate having a front surface to which a processing liquid is supplied in a state of holding the substrate, comprising:
a base end portion detachably attached to a base; and
a claw portion connected to the base end portion and configured to come into contact with a periphery of the substrate to grip the substrate.
